(19) United States
(12) Patent Application Publication
(10) Pub. No.: US 2020/0095839 A1
(43) Pub. Date: Mar. 26, 2020

(54) Degradable Components and Tools

(71) Applicant: BOSS COMPLETIONS LTD., Sylvan Lake (CA)

(72) Inventors: Kelsey James Kalinski, Sylvan Lake (CA); Martin Alejandro Marini, Sylvan Lake (CA); Kevin Reynald Beck, Sylvan Lake (CA)

(21) Appl. No.: 16/575,793

(22) Filed: Sep. 19, 2019

Related U.S. Application Data
(60) Provisional application No. 62/735,542, filed on Sep. 24, 2018.

(51) Int. Cl. E21B 29/02; E21B 33/129; C04B 41/00; C04B 41/90; C04B 41/51; C23C 16/06

(52) U.S. Cl. CPC E21B 29/02; E21B 33/129; C04B 41/009; C23C 16/06; C04B 41/5155; C04B 41/5144; C04B 41/90

(57) ABSTRACT

A degradable device component or tool provided with one or more target physical parameter values and shaped from a precursor composite material. The precursor composite material includes a core material in particulate form having one or more real physical parameter values exceeding the target physical parameter values; a first layer material provided on the core material and a second layer material provided on the first layer material, wherein the first layer material and the second layer material are together capable of forming a galvanic cell; and a melted outer layer material provided directly or indirectly on the second layer, the outer layer having a melting point below the melting points of the core material, the first layer material and the second layer material.

### CROSS-REFERENCE TO RELATED APPLICATIONS

This application claims priority from U.S. Provisional Application Ser. No. 62/735,542 filed on Sep. 24, 2018, the entire disclosure of which is incorporated herein by reference.

### FIELD OF THE INVENTION

The invention relates to degradable composite materials for manufacture of degradable devices, device components and tools and more particularly to manufacture of such devices, components and tools with target physical properties based on selection of core materials together with materials to promote degradation of the devices and tools upon completion of their desired function.

### BACKGROUND

There are many examples of devices and tools which are required for single use. In many situations after such devices and tools have performed their desired function, it is desirable to remove them from the operating environment and dispose of them. This problem has been addressed by providing devices, components thereof, and tools which are degradable. The application of degradable devices and tools is particularly well suited to downhole devices and tools used in the oil and gas industry.

A wide variety of downhole tools may be used within a wellbore in connection with producing hydrocarbons or reworking a well that extends into a hydrocarbon formation. Downhole tools such as frac plugs, bridge plugs, and packers, for example, may be used to seal a component against casing along the wellbore wall or to isolate one pressure zone of the formation from another.

After the production or reworking operation is complete, these downhole tools must be removed from the wellbore. Tool removal has conventionally been accomplished by complex retrieval operations, or by milling or drilling the tool out of the wellbore mechanically. Thus, downhole tools are either retrievable or disposable. Another more recent solution is to make such downhole tools degradable in salts or other media which either exist naturally in fluids emerging from a wellbore or which are pumped into the wellbore. One such example is the X-Factor™ dissolvable fracturing plug produced by Nexgen Oil Tools (San Antonio, Tex., USA; www.nexgenoiltools.com). It is indicated that this plug dissolves in fresh water over 24-48 hours.

Examples of degradable portions of additional downhole tools and/or related technologies are described in US Patent Publication Nos. 20180245422, 20180238133, 20140262327, 20140020911, 20120292053, 20050205266, and U.S. Pat. No. 8,047,279, each of which is incorporated herein by reference in its entirety.

There continues to be a need to improve the properties of degradable devices and tools, including, but not limited to degradable downhole tools used in the oil and gas industry.

### SUMMARY

According to one aspect of the invention, there is provided a process for manufacture of a degradable device component or tool, the process comprising: selecting one or more target physical parameter values for the device component or tool to meet a desired performance threshold for the device component or tool; selecting a core material having one or more real physical parameter values exceeding the target physical parameter values; identifying a first layer material and a second layer material, the first and second layer materials together capable of forming a galvanic cell when the first layer material is provided on the core material and the second layer material is provided on the first layer material; identifying an outer layer material, wherein the melting point of the outer layer material is below the melting points of the core material, the first layer material and the second layer material; providing the core material in particulate form, adding the first layer material to the core material, adding the second layer material to the first layer material and adding the outer layer material directly or indirectly to the second layer material to produce a precursor composite material; and heating and the precursor composite material to melt the outer layer material and shaping the precursor composite material to form the device component or tool.

In some embodiments, the process further comprises adding at least one intermediate layer material between the second layer material and the outer layer material.

In some embodiments of the process, the step of adding the first layer material to the core material comprises coating the first layer on the core material.

In some embodiments of the process, the step of coating the first layer material on the core material comprises coating by chemical vapor deposition.

In some embodiments of the process, the step of adding the second layer material to the first layer material comprises coating the second layer material on the first layer material.

In some embodiments of the process, the step of coating the second layer material on the first layer material comprises coating by chemical vapor deposition.

In some embodiments of the process, the step of adding the outer layer material comprises coating the outer layer material on the second layer material.

In some embodiments of the process, the step of coating the outer layer material on the second layer material comprises coating by chemical vapor deposition.

In some embodiments of the process, the step of adding the intermediate layer material between the second layer material and the outer layer material comprises coating the intermediate layer material on the second layer material.

In some embodiments of the process, the step of coating the intermediate layer material on the second layer material comprises coating by chemical vapor deposition.

In some embodiments of the process, the target physical parameters include one or more of hardness, elastic modulus, stiffness, elongation, tensile strength, density, impact strength, compressive strength, shear strength, thermal expansion, and conductivity.

In some embodiments of the process, the difference between the anodic index of the first coating material and the anodic index of the second coating material is greater than about 0.4.

In some embodiments of the process, the particulate form of the core material is a powder, a hollow microsphere or a solid microsphere.

In some embodiments of the process, the core material, the first material, the second material and the outer layer are selected from the group consisting of metals, alloys and ceramics.

In some embodiments of the process, the step of shaping the precursor composite material comprises pressing in a hard die, cold isostatic pressing or metal injection molding.

In some embodiments of the process, the step of shaping the precursor composite material comprises: dynamic forging, P/M forging, hot isostatic pressing, laser processing, sintering, pulse sintering, ARCAM, spark plasma sintering (SPS), forging in a granular bed of particles, metal injection molding, laser-engineered net shaping, conventional forging in a mold, direct consolidation of powders by the use of rapid pressure molding, a plasma process, a thermal spray process, an e-beam process, squeeze casting, liquid phase sintering with pressurization, liquid phase sintering without pressurization, vacuum hot pressing, electro-consolidation, extrusion or ECAP extrusion.

In some embodiments of the process, the process further comprises the steps of post processing the precursor composite material by any one of or a combination of coating, extruding, machining, polishing, anodizing and heat treating.

Another aspect of the invention is a degradable device component or tool provided with one or more target physical parameter values and shaped from a precursor composite material, the precursor composite material comprising: a core material in particulate form having one or more real physical parameter values exceeding the target physical parameter values; a first layer material provided on the core material and a second layer material provided on the first layer material, wherein the first layer material and the second layer material are together capable of forming a galvanic cell; and a melted outer layer material provided directly or indirectly on the second layer, the outer layer having a melting point below the melting points of the core material, the first layer material and the second layer material.

In some embodiments of the degradable device component or tool, at least one intermediate layer material is provided between the second layer material and the outer layer material.

In some embodiments of the degradable device component or tool, the first layer material is coated on the core material.

In some embodiments of the degradable device component or tool, the first layer material is coated on the core material by chemical vapor deposition.

In some embodiments of the degradable device component or tool, the second layer material is coated on the first layer material.

In some embodiments of the degradable device component or tool, the second layer material is coated on the first layer material by chemical vapor deposition.

In some embodiments of the degradable device component or tool, the outer layer material is coated on the second layer material and the outer layer material has sufficient porosity to permit electrolytes to pass therethrough.

In some embodiments of the degradable device component or tool, the outer layer material on the is coated on the second layer material by chemical vapor deposition.

In some embodiments of the degradable device component or tool, the intermediate layer material is coated on the second layer material.

In some embodiments of the degradable device component or tool, the intermediate layer material is coated on the second layer material by chemical vapor deposition.

In some embodiments of the degradable device component or tool, the target physical parameters include one or more of hardness, elastic modulus, stiffness, elongation, tensile strength, density, impact strength, compressive strength, shear strength, thermal expansion, and conductivity.

In some embodiments of the degradable device component or tool, the difference between the anodic index of the first coating material and the anodic index of the second coating material is greater than about 0.4.

In some embodiments of the degradable device component or tool, the particulate form of the core material is a powder, a hollow microsphere or a solid microsphere.

In some embodiments of the degradable device component or tool, the core material, the first material, the second material and the outer layer are selected from the group consisting of metals, alloys and ceramics.

In some embodiments of the degradable device component or tool, the shaped precursor composite material is shaped by pressing in a hard die, cold isostatic pressing or metal injection molding.

In some embodiments of the degradable device component or tool, the shaped precursor composite material is shaped by: dynamic forging, P/M forging, hot isostatic pressing, laser processing, sintering, pulse sintering, ARCAM, spark plasma sintering (SPS), forging in a granular bed of particles, metal injection molding, laser-engineered net shaping, conventional forging in a mold, direct consolidation of powders by the use of rapid pressure molding, a plasma process, a thermal spray process, an e-beam process, squeeze casting, liquid phase sintering with pressurization, liquid phase sintering without pressurization, vacuum hot pressing, electro-consolidation, extrusion or ECAP extrusion.

In some embodiments of the degradable device component or tool, the shaped precursor composite material is finished by post processing the precursor composite material by any one of or a combination of coating, extruding, machining, polishing, anodizing and heat treating.

In some embodiments of the degradable device component or tool, the device component is a button for holding a fracturing plug in a well casing.

In some embodiments of the degradable device component or tool, the core material is tungsten carbide, the first layer material is magnesium, the second layer material is nickel and the outer layer material is aluminum.

In some embodiments of the degradable device component or tool, the core material is tungsten carbide, the first layer material is magnesium, the second layer material is nickel, the intermediate layer is aluminum and the outer layer material is zinc.

In some embodiments of the degradable device component or tool, the target physical parameter values include a hardness of greater than about 30 HRC.

Another aspect of the invention is a process for manufacture of a degradable device component or tool, the process comprising: selecting one or more target physical parameter values for the device component or tool to meet a desired performance threshold for the device component or tool; selecting a core material having one or more real physical parameter values exceeding the target physical parameter values; identifying a first material and a second material, the first and second materials together capable of forming a galvanic cell when present in sufficient amounts in particulate form in a homogeneous mixture of one or more additional materials, including the core material; preparing a homogeneous mixture of the core material in particulate form, the first material in particulate form and the second material in particulate form; and heating and shaping the homogeneous mixture to form the device component or tool.

In some embodiments of the process, the target physical parameters include one or more of hardness, elastic modulus, stiffness, elongation, tensile strength, density, impact strength, compressive strength, shear strength, thermal expansion, and conductivity.

In some embodiments of the process, the difference between the anodic index of the first coating material and the anodic index of the second coating material is greater than about 0.4.

In some embodiments of the process, the particulate form of the core material is a powder, a hollow microsphere or a solid microsphere.

In some embodiments of the process, the particulate form of the first material is a powder, a hollow microsphere or a solid microsphere.

In some embodiments of the process, the particulate form of the second material is a powder, a hollow microsphere or a solid microsphere.

In some embodiments of the process, the core material, the first material, and the second material are selected from the group consisting of metals, alloys and ceramics.

In some embodiments of the process, the homogeneous mixture further comprises one or more binders or additives.

In some embodiments of the process, the step of shaping the precursor composite material comprises: dynamic forging, P/M forging, hot isostatic pressing, laser processing, sintering, pulse sintering, ARCAM, spark plasma sintering (SPS), forging in a granular bed of particles, metal injection molding, laser-engineered net shaping, conventional forging in a mold, direct consolidation of powders by the use of rapid pressure molding, a plasma process, a thermal spray process, an e-beam process, squeeze casting, liquid phase sintering with pressurization, liquid phase sintering without pressurization, vacuum hot pressing, electro-consolidation, extrusion or ECAP extrusion.

In some embodiments of the process, the process further comprises the steps of post processing the precursor composite material by any one of or a combination of coating, extruding, machining, polishing, anodizing and heat treating.

### BRIEF DESCRIPTION OF THE DRAWINGS

Various objects, features and advantages of the embodiments described herein are illustrated in the accompanying drawings.

FIG. 1A is a schematic representation of one embodiment of a degradable tubular tool 10.

FIG. 1B is a magnification of the sidewall of the degradable tubular tool 10 indicating the layers of the sidewall of the degradable tubular tool 10.

### DETAILED DESCRIPTION

### Rationale and Introduction

Conventional degradable downhole tools have several shortcomings. One problem is that it has been difficult to replicate the target physical characteristics of the metals and alloys which are provided by conventional non-degradable tools. In one example, applicable to downhole tools in the oil and gas industry, the casing-contacting surfaces of a fracturing plug must be provided with sufficient hardness and/or shear strength to engage the inner surface of the casing with sufficient friction to be securely tightened against the inner surface of the casing and to not be dislodged by the high pressures of fluids exerted against the fracturing plug during a fracturing operation. If the fracturing plug fails to remain securely engaged with the casing during a fracturing operation, the operation will either fail or become less effective. This scenario also applies to other devices and tools designed for use outside of the oil and gas industry and with respect to any desirable physical parameters.

Furthermore, it is believed by many experts that degradable plugs have not yet lived up to their initial promise to reduce the total cost of completion operations, and some experts are skeptical of claims that these high-tech plugs reliably disappear without impeding flowback or production.

It is therefore advantageous to develop improved degradable devices, components thereof or tools that have physical parameters which meet or exceed the requirements for successful operation of the devices or tools. This is a challenging problem. The present inventors have recognized that metal composites based on a core material which exceeds a value of a given target physical parameter for the device or tool will provide the basis for improving the function of devices or tools formed from metal composite. The core material is then coated or mixed with a first material and a second material, which will form a galvanic cell under the operating conditions of the device or tool in the case of coated materials, or a disintegration process in the case of mixed materials. This galvanic cell forms the basis for degrading the tool because the ions are released from either the first material or the second material or both the first and second materials in the electrochemical galvanic process. The materials used for the galvanic cell in most of the examples described hereinbelow are magnesium and nickel. Another possibility is aluminum and graphite, (less effective for degradation but providing stronger mechanical properties). In certain embodiments, in the case of a core material mixed with a first material and a second material, one of the materials a non-metallic material such as a ceramic or a salt. The combination of the core material and the first and second materials is then processed as required to form the device, device component or tool as described in examples presented hereinbelow. The additional processing may include adding additional materials such as binders and/or additives to the composite as required to obtain a precursor which is then shaped into the form of the device or tool.

While the composite precursor would not be expected to have the same physical properties as the core material, if the core material is properly chosen in accordance with embodiments of the invention to provide target physical property values significantly higher than required for the device or tool, the subsequent reduction in the target physical values as a result of preparation of the composite precursor will remain above their desired levels, thereby providing a device or tool with the desired functionality.

The embodiments of the present disclosure are directed toward degradable devices, components thereof and tools. Examples in the oil and gas industry include, but are not limited to fracturing plugs, bridge plugs, and packers or components thereof (for example, slip bands or buttons). As used herein, the term “degradable” and all of its grammatical variants (e.g., “degrade,” “degradation,” “degrading,” “dissolve,” dissolving,” and the like), refers to the dissolution or chemical conversion of solid materials such that reduced-mass solid end products result or reduced structural integrity results by at least one of solubilization, hydrolytic degradation, biologically formed entities (e.g., bacteria or enzymes), chemical reactions (including electrochemical and galvanic reactions), thermal reactions, reactions induced by radiation, or combinations thereof. In complete degradation, no solid end products result, or structural shape is lost. In some instances, the degradation of the material may be sufficient for the mechanical properties of the material to be reduced to a point that the material no longer maintains its integrity and falls apart or sloughs off into its surroundings. The conditions for degradation are generally wellbore conditions where an external or internal stimulus may be used to initiate or effect the rate of degradation, where the external stimulus is naturally occurring in the wellbore (e.g., pressure, temperature) or introduced into the wellbore (e.g., fluids, chemicals), and the internal stimulus is innate to the material, containing in its matrix the catalyst for its disintegration. For example, the pH of the fluid that interacts with the material may be changed by introduction of an acid or a base, or an electrolyte may be introduced or naturally occurring to induce galvanic corrosion. The term “wellbore environment,” and grammatical variants thereof, includes both naturally occurring wellbore environments and materials or fluids introduced into the wellbore. The term “at least a portion,” and grammatical variants thereof, with reference to a component having at least a portion composed thereof of a degradable material or substance (e.g., “at least a portion of a component is degradable” or “at least a portion of the slips and/or slip bands is degradable,” and variants thereof) refers to at least about 80% of the volume of that part being formed of the degradable material or substance.

The term “hardness,” as used herein, refers to the ability of a material to resist plastic deformation, usually by indentation. The Rockwell scale (HRC) is a typically used hardness scale and is used herein.

The terms “yield strength,” and “yield stress,” as used herein, refer to the material property defined as the stress at which a material begins to deform plastically. Yield strength is the critical material property exploited by many fundamental techniques of material-working: to reshape material with pressure (such as forging, rolling, pressing, bending, extruding, or hydroforming), to separate material by cutting (such as machining) or shearing, and to join components rigidly with fasteners. Yield strength may be expressed in units of thousands of pounds per square inch (Ksi).

The term “elongation” refers to the increase in length which occurs before a metal is fractured, when subjected to stress. This is usually expressed as a percentage of the original length and is a measure of the ductility of the metal.

As used herein, the term “chemical vapor deposition” refers to a deposition method used to produce high quality, high-performance, solid materials, typically under vacuum. In typical chemical vapor deposition, the substrate is exposed to one or more volatile precursors, which react and/or decompose on the substrate surface to produce the desired deposit.

Various aspects of the invention will now be described with reference to the drawings and examples. Several possible alternative features are introduced during the course of this description. It is to be understood that, according to the knowledge and judgment of persons skilled in the art, such alternative features may be substituted in various combinations to arrive at different embodiments of the present invention even if such combinations are not explicitly recited in the ensuing description.

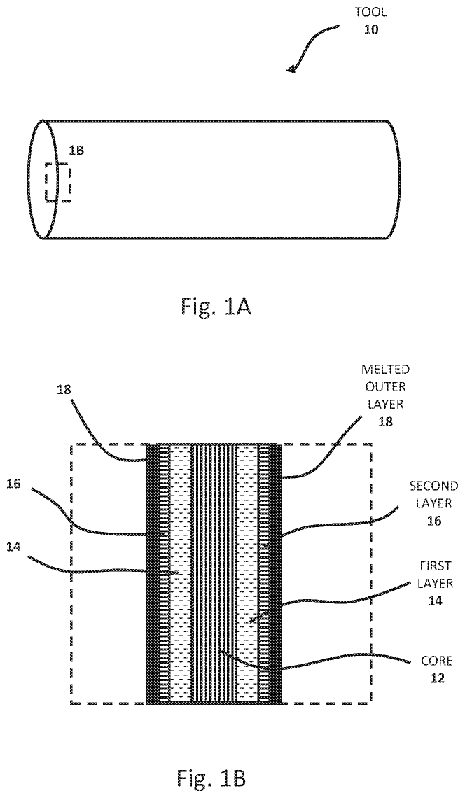

FIG. 1A is a schematic representation of a degradable tubular tool 10. This degradable tool 10 is provided with one or more target physical characteristics as described herein and shaped from a precursor composite material. It is seen in FIG. 1B that the composite material is formed of a series of layers. The body of the sidewall of the tubular tool 10 includes a core material 12, a first layer material 14 provided on the core material 12, a second layer material 16 on the first layer material 14, and a melted outer layer material 18 on the second layer material 16. In some embodiments, the core material is provided in particulate form and the first layer material 14 and second layer material 16 are together capable of forming a galvanic cell under suitable conditions, including the presence of an electrolyte, for example. The melted outer layer 18 has a melting point below the melting points of the first layer material 14 and second layer material 16 in order to permit coating of the outer layer 18 on the second layer material 16. With this arrangement, activation of the galvanic cell will degrade the second layer material 16 and first layer material 14, thereby causing degradation of the tool 10. In one embodiment, activation of the galvanic cell is accomplished by providing a relatively thin porous outer layer 18 which permits absorption of electrolytes (such as simple salts) therethrough where they subsequently make contact with the second layer material 16 and the first layer material 14. It is expected that the degree of porosity of the outer layer 18 required to permit electrolytes to migrate therethrough will be established without undue experimentation. Flow of electrons between the first layer material 14 and second layer material 16 then causes degradation of at least one of the second layer material 16 and the first layer material 14, causing the tool 10 to become degraded. In some embodiments, the outer layer 18 may be have a salt such as NaCl or KCl placed thereon prior to deployment of the tool 10. As long as the tool 10 remains dry, the salt will not migrate significantly through the outer layer 18. When placed in a predominately aqueous environment (such as a downhole environment, for example), the salt will become mobilized and permeate through the outer layer 18 to reach the second layer material 16 and the first layer material 14, thereby activating the galvanic cell which causes degradation of the tool 10.

### EXAMPLES

### Example 1: Manufacture of Degradable Buttons for a Fracturing Plug Using a Four Component Composite Composition with Tungsten Carbide as Core Material

This example describes manufacture of degradable buttons for installation on slip members of a mandrel of a fracturing plug. These degradable buttons are provided to contact the inner sidewall of the well casing and engage thereto with application of sufficient force to cause the buttons to dig into the casing, deform to some degree and hold the plug within the casing. Subsequent degradation of the buttons, as desired, will cause the plug to become dislodged from its engaged position, as desired.

In this example, the degradable buttons are manufactured according to one embodiment of the invention. The buttons may be fixed to the slip members by any conventional attachment means such as epoxy resins for example, provided that the attachment means is sufficiently strong to retain the buttons in place when the fracturing plug is set in the casing.

For manufacture of the degradable buttons, a first consideration is the target physical properties required to provide the desired functionality, namely, the required hardness, elongation and shear strength to engage with the casing. In this example, there is just one target physical property: hardness greater than about 30 HRC (Rockwell scale).

Tungsten carbide was selected as a core material for preparing a composite precursor to manufacture the degradable buttons. Tungsten carbide has a hardness of 70 HRC, which is well above the target of 30 HRC, to allow the buttons to dig into the casing without crushing.

The tungsten carbide was provided as a 325-mesh, 44-micron powder. The tungsten carbide powder was placed in a reactor for chemical vapor deposition, coated with magnesium and then coated with nickel in a different chemical vapor deposition reactor. A final coating of aluminum was then added, also by chemical vapor deposition in a separate reactor to provide a composite with a core of tungsten carbide powder and approximately equal layers of magnesium, nickel and aluminum such that the composite composition was about 97% tungsten carbide, about 1% magnesium, about 1% nickel and about 1% aluminum by weight. This composition was shaped by forging but the shaping was found to be unsuccessful due to poor binding of materials to each other. However, the degradation test indicated that the galvanic cell operates as intended to cause the desired degradation of the composition.

### Example 2: Manufacture of Degradable Buttons for a Fracturing Plug Using a Four Component Composite Composition with Tungsten Carbide as Core Material

With the limited success of the first example, a second composite composition is now envisioned, which is similar to the composite described in Example 1, with the exception that an additional outer layer of zinc is to be provided, also by chemical vapor deposition to provide a composite precursor having layers of magnesium, nickel and aluminum such that the composite composition is about 96% tungsten carbide, about 1% magnesium, about 1% nickel, about 1% aluminum, and about 1% zinc by weight. This will allow lowering of the temperature required to melt the outer layer, which is an important aspect in the process of shaping the precursor composite. It is believed that sintering at a temperature at or above 400° C. will result in sufficient bonding of the components of the composite because the outer layer of zinc will become melted without the risk of approaching the melting point of magnesium at 650° C. Forging, extrusion or other specialized heat-based processes may also be investigated for shaping the precursor into the buttons.

### Example 3: Manufacture of Degradable Buttons for a Fracturing Plug Using a Three Component Composite Composition with AISI 4140 Alloy Steel as Core Material

In this example, buttons are manufactured using a precursor composition with AISI 4140 alloy steel powder as core material with first and second layers as described in Examples 1 and 2 in powder form, or alternative first and second materials in powder form mixed to produce a homogeneous mixture without chemical vapor deposition. The target physical properties are elongation above 15% and yield strength above 80 Ksi. The mixture of three materials is forged into billets which are then machined to produce the degradable buttons having expected characteristics of elongation above 15% and yield strength above 80 Ksi.

### Example 4: Manufacture of Degradable Buttons for a Fracturing Plug Using an Alternative Three Component Composite Composition with Tungsten Carbide as Core Material

In this example, tungsten carbide is employed as the core material and the first and second materials are titanium and nickel to provide a galvanic cell. As in Examples 1 and 2, the target physical property is hardness of 30 HRC. The three materials in powder form are mixed to provide a homogeneous mixture and the mixture is forged into billets which are then machined to produce the degradable buttons having expected hardness above 30 HRC.

### EQUIVALENTS AND SCOPE

Other than described herein, or unless otherwise expressly specified, all of the numerical ranges, amounts, values and percentages, such as those for amounts of materials, elemental contents, times and temperatures, ratios of amounts, and others, in the following portion of the specification and attached claims may be read as if prefaced by the word “about” even though the term “about” may not expressly appear with the value, amount, or range. Accordingly, unless indicated to the contrary, the numerical parameters set forth in the following specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Any patent, publication, internet site, or other disclosure material, in whole or in part, that is said to be incorporated by reference herein is incorporated herein only to the extent that the incorporated material does not conflict with existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

Unless otherwise defined, all technical and scientific terms used herein have the same meaning as commonly understood by one of ordinary skill in the art to which this invention belongs.

While this invention has been particularly shown and described with references to example embodiments thereof, it will be understood by those skilled in the art that various changes in form and details may be made therein without departing from the scope of the invention encompassed by the appended claims.

In the claims, articles such as “a,” “an,” and “the” may mean one or more than one unless indicated to the contrary or otherwise evident from the context. Claims or descriptions that include “or” between one or more members of a group are considered satisfied if one, more than one, or all of the group members are present in, employed in, or otherwise relevant to a given product or process unless indicated to the contrary or otherwise evident from the context.

It is also noted that the term “comprising” is intended to be open and permits but does not require the inclusion of additional elements or steps. When the term “comprising” is used herein, the term “consisting of” is thus also encompassed and disclosed. Where ranges are given, endpoints are included. Furthermore, it is to be understood that unless otherwise indicated or otherwise evident from the context and understanding of one of ordinary skill in the art, values that are expressed as ranges can assume any specific value or subrange within the stated ranges in different embodiments of the invention, to the tenth of the unit of the lower limit of the range, unless the context clearly dictates otherwise. Where the term “about” is used, it is understood to reflect +/−10% of the recited value. In addition, it is to be understood that any particular embodiment of the present invention that falls within the prior art may be explicitly excluded from any one or more of the claims. Since such embodiments are deemed to be known to one of ordinary skill in the art, they may be excluded even if the exclusion is not set forth explicitly herein.

What is claimed is:

1. A degradable device component or tool provided with one or more target physical parameter values and shaped from a precursor composite material, the precursor composite material comprising:
a core material in particulate form having one or more real physical parameter values exceeding the target physical parameter values;
a first layer material provided on the core material and a second layer material provided on the first layer material, wherein the first layer material and the second layer material are together capable of forming a galvanic cell; and
a melted outer layer material provided directly or indirectly on the second layer, the outer layer having a melting point below the melting points of the core material, the first layer material and the second layer material.

2. The device component or tool of claim 1, wherein at least one intermediate layer material is provided between the second layer material and the outer layer material.

3. The device component or tool of claim 1, wherein the first layer material is coated on the core material.

4. The device component or tool of claim 3, wherein the first layer material is coated on the core material by chemical vapor deposition.

5. The device component or tool of claim 1, wherein the second layer material is coated on the first layer material.

6. The device component or tool of claim 5, wherein the second layer material is coated on the first layer material by chemical vapor deposition.

7. The device component or tool of claim 1, wherein the outer layer material is coated on the second layer material and the outer layer material has sufficient porosity to permit electrolytes to pass therethrough.

8. The device component or tool of claim 7, wherein the outer layer material on the is coated on the second layer material by chemical vapor deposition.

9. The device component or tool of claim 2, wherein the intermediate layer material is coated on the second layer material.

10. The device component or tool of claim 9, wherein the intermediate layer material is coated on the second layer material by chemical vapor deposition.

11. The device component or tool of claim 1, wherein the target physical parameters include one or more of hardness, elastic modulus, stiffness, elongation, tensile strength, density, impact strength, compressive strength, shear strength, thermal expansion, and conductivity.

12. The device component or tool of claim 1, wherein the difference between an anodic index of the first coating material and an anodic index of the second coating material is greater than about 0.4.

13. The device component or tool of claim 1, wherein the particulate form of the core material is a powder, a hollow microsphere or a solid microsphere.

14. The device component or tool of claim 1, wherein the core material, the first material, the second material and the outer layer are selected from the group consisting of: metals, alloys and ceramics.

15. The device component or tool of claim 1, wherein the precursor composite material is shaped by: pressing in a hard die, cold isostatic pressing or metal injection molding.

16. The device component or tool of claim 1, wherein the precursor composite material is shaped by: dynamic forging, P/M forging, hot isostatic pressing, laser processing, sintering, pulse sintering, ARCAM, spark plasma sintering (SPS), forging in a granular bed of particles, metal injection molding, laser-engineered net shaping, conventional forging in a mold, direct consolidation of powders by the use of rapid pressure molding, a plasma process, a thermal spray process, an e-beam process, squeeze casting, liquid phase sintering with pressurization, liquid phase sintering without pressurization, vacuum hot pressing, electro-consolidation, extrusion or ECAP extrusion.

17. The device component or tool of claim 16 wherein the precursor composite material is finished by post processing the precursor composite material by any one of or a combination of coating, extruding, machining, polishing, anodizing and heat treating.

18. The device component or tool of claim 1, wherein the device component is a button for holding a fracturing plug in a well casing.

19. The device component or tool of claim 18, wherein the core material is tungsten carbide, the first layer material is magnesium, the second layer material is nickel and the outer layer material is aluminum.

20. The device component or tool of claim 18, wherein the core material is tungsten carbide, the first layer material is magnesium, the second layer material is nickel, the intermediate layer is aluminum and the outer layer material is zinc.

21. The device component or tool of claim 18, wherein the target physical parameter values include a hardness of greater than about 30 HRC.
